(19) United States
(12) Patent Application Publication
(10) Pub. No.: US 2015/0377964 A1
(43) Pub. Date: Dec. 31, 2015

(54) PROGRAMMABLE TEST PATTERN FOR A PIXEL ARRAY

(71) Applicant: Texas Instruments Incorporated, Dallas, TX (US)

(72) Inventors: Raja Reddy PATUKURI, Nizamabad (IN); Jagannathan Venkataraman, Bangalore (IN)

(21) Appl. No.: 14/755,728

(22) Filed: Jun. 30, 2015

(30) Foreign Application Priority Data
Jun. 30, 2014 (IN) 3178/CHE/2014

(51) Int. Cl. G01R 31/3187; G01S 17/02; H04N 17/00

(52) U.S. Cl. CPC G01R 31/3187; H04N 17/002; G01S 17/02

(57) ABSTRACT

The disclosure provides a circuit capable of generating programmable test patterns for a pixel array. The circuit includes a pixel array having a plurality of pixels arranged in a plurality of rows and a plurality of columns. A built-in-tester is coupled to the pixel array. The built-in-tester includes a data pattern register that generates a plurality of test patterns. A switching logic circuit is coupled between the data pattern register and the pixel array. The switching logic circuit provides to each column of the plurality of columns one of a first voltage and a second voltage based on a test pattern of the plurality of test patterns received from the data pattern register.

### CROSS REFERENCES TO RELATED APPLICATIONS

This application claims priority from India provisional patent application No. 3178/CHE/2014 filed on Jun. 30, 2014 which is hereby incorporated by reference in its entirety.

### TECHNICAL FIELD

The present disclosure is generally related to testing a read circuit of a pixel array, and more particularly to generating programmable test patterns for a pixel array in a time-of-flight (TOF) system.

### BACKGROUND

An emerging category of electronic devices is time-of-flight (TOF) systems. The TOF systems find applications in accelerometers, monolithic gyroscopes, light sensors, conveyor belts, depth sensing, proximity sensing, gesture recognition and imagers. A TOF system includes a light source that emits light pulses. The light pulses are emitted towards a target, which reflects the light pulses. The target is any object of interest which may include, but not limited to, a human, an automated component, an animal, an electronic device etc. A TOF sensor in the TOF system receives the reflected light pulses. The TOF sensor receives the reflected light pulses after a time of flight, which is proportional to a distance of the target from the TOF system.

The TOF sensor includes a pixel array having a plurality of pixels. The pixel array receives the reflected light pulses. The pixel array collects light for a predetermined amount of time after the emission of the light by the light source. Light reflected from a far away object travels a longer distance and therefore has a longer time-of-flight, whereas light reflected from a nearby object is received after short time-of-flight. A pixel in the pixel array demodulates the reflected light, and generates an output proportional to the time-of-flight. Distance information is therefore extracted from the output generated by the pixel.

The image formed from the pixel array suffers from an image artifact due to poor settling time of a circuit used in conjunction with the pixel array. The image artifacts are caused by following factors, but not limited to, coupling effect on common bias, shared voltage references, memory effects caused by high speed analog multiplexer. The characterization of such image becomes difficult, and the amount of image artifact cannot be quantified. To measure and characterize the image artifact, multiple test patterns need to be captured with pixel level position accuracy. This is difficult, time consuming and requires manual intervention.

### SUMMARY

According to an aspect of the disclosure, a circuit is disclosed. The circuit includes a pixel array having a plurality of pixels arranged in a plurality of rows and a plurality of columns. A built-in-tester is coupled to the pixel array. The built-in-tester includes a data pattern register that generates a plurality of test patterns. A switching logic circuit is coupled between the data pattern register and the pixel array. The switching logic circuit provides to each column of the plurality of columns one of a first voltage and a second voltage based on a test pattern of the plurality of test patterns received from the data pattern register.

### BRIEF DESCRIPTION OF THE VIEWS OF DRAWINGS

FIG. 1 illustrates a circuit;

FIG. 2(a) and FIG. 2(b) illustrates a circuit, according to an embodiment;

FIG. 3(a) to FIG. 3(i) illustrates test patterns generated by a circuit, according to an embodiment;

FIG. 4 is a flowchart to illustrate a method of operation of a circuit, according to an embodiment;

FIG. 5 is a flowchart to illustrate a method of reading a pixel array, according to an embodiment; and

FIG. 6 illustrates a time-of-flight (TOF) system, according to an embodiment.

### DETAILED DESCRIPTION OF THE EMBODIMENTS

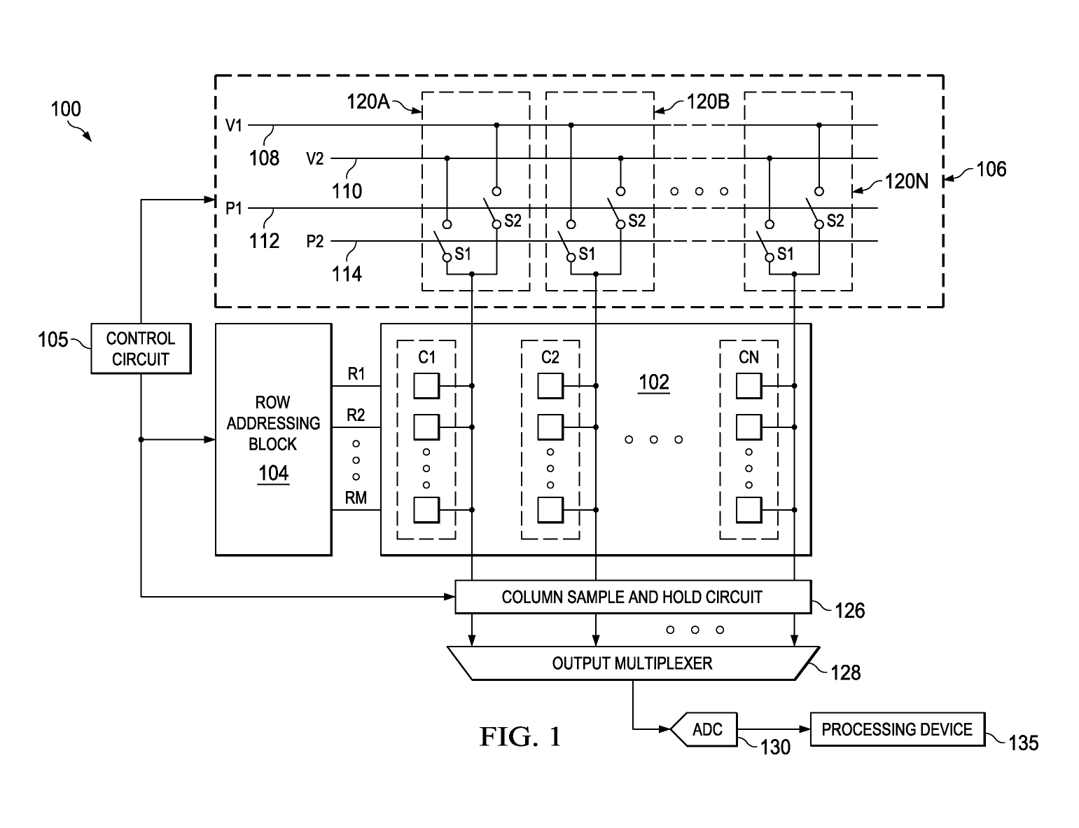

FIG. 1 illustrates a circuit 100. The circuit 100 includes a pixel array 102, a row addressing block 104, a control circuit 105, a switching logic circuit 106, a column sample and hold circuit 126, an output multiplexer 128 and an analog to digital converter (ADC) 130. The pixel array 102 includes a plurality of pixels arranged in a plurality of rows and a plurality of columns. The pixel array 102 is illustrated to have M rows represented as R1, R2 to RM, and N columns represented as C1, C2 to CN. M and N are positive integers greater than or equal to one.

The row addressing block 104, the switching logic circuit 106 and the column sample and hold circuit 126 are coupled to the pixel array 102. The control circuit 105 is coupled to the row addressing block 104, the switching logic circuit 106 and the column sample and hold circuit 126. The output multiplexer 128 is coupled to the column sample and hold circuit 126. The ADC 130 is coupled to the output multiplexer 128. A processing device 135 is coupled to the ADC 130.

The switching logic circuit 106 includes a plurality of selection circuits illustrated as 120A, 120B to 120N. Each selection circuit of the plurality of selection circuits corresponds to a column of the plurality of columns. For example, selection circuit 120A corresponds to column C1, selection circuit 120B corresponds to column C2, and selection circuit 120N corresponds to column CN.

Each selection circuit includes a first switch S1 and a second switch S2. The first switch S1 and the second switch S2 are coupled to one of a first voltage V1 108 and a second voltage V2 110. For example, in selection circuit 120A, the first switch S1 is coupled to the second voltage V2 110, and the second switch S2 is coupled to the first voltage V1 108. In selection circuit 120B, the first switch S1 is coupled to the first voltage V1 108, and the second switch S2 is coupled to the second voltage V2.

The switching logic circuit 106 receives control lines represented as P1 and P2. The control line P1 activates the second switch S2 in each of the selection circuits, and the control line P2 activates the first switch S1 in each of the selection circuits.

The operation of the circuit 100 illustrated in FIG. 1 is explained now. The control circuit 105 provides a row address to the row addressing block 104. The row addressing block 104 activates a row based on the row address provided by the control circuit 105. The control circuit 105 also provides a column address to the column sample and hold circuit 126. The column sample and hold circuit 126 activates a column based on the column address provided by the control circuit 105.

The circuit 100 operates in a normal mode and a test mode. In the normal mode, the plurality of pixels in the pixel array 102 is charged to a reset voltage. When a sensor having the pixel array 102 receives the light pulses, the plurality of pixels in the pixel array 102 discharge from their original voltage levels. The pixels discharge and attain a voltage lower than the reset voltage based on the intensity of light pulses and exposure time of the pixel array 102 to the light pulses.

The row addressing block 104 activates a row based on the row address provided by the control circuit 105. For example, row R1 is activated by the row addressing block 104. The voltages stored in all the pixels in row R1 is transferred to the column sample and hold circuit 126.

The column sample and hold circuit 126 stores the voltages received from the pixel array 102. The control circuit 105 also provides a column address to the column sample and hold circuit 126. The column sample and hold circuit 126 activates a column based on the column address provided by the control circuit 105.

The column sample and hold circuit 126 provides the stored voltages corresponding to the row R1 to the output multiplexer 128, and the output multiplexer 128 generates a voltage corresponding to the column activated by the column sample and hold circuit 126. The ADC 130 receives the voltage generated by the output multiplexer 128, and generates a corresponding code.

The above step is repeated for all the pixels in row R1. The ADC 130 generates a code corresponding to each pixel in the pixel array 102. The codes obtained corresponding to the pixel array 102 are processed in the processing device 135 coupled to the circuit 100. The processing device 135 generates an image based on the codes received from the ADC 130.

The circuit 100 also operates in the test mode. In test mode, the control circuit 105 activates one of the control line P1 and the control line P2. When the control line P1 is selected, the column C1 receives the first voltage V1 108, the column C2 receives the second voltage V2 110, and the column CN receives the first voltage V1 108.

When the control line P2 114 is selected, the column C1 receives the second voltage V2 110, the column C2 receives the first voltage V1 108 and the column CN receives the second voltage V2 110. The voltages across each of the columns is provided to the column sample and hold circuit 126. The column sample and hold circuit 126 stores the voltages received from the pixel array 102. The control circuit 105 also provides a column address to the column sample and hold circuit 126. The column sample and hold circuit 126 activates a column based on the column address provided by the control circuit 105.

The column sample and hold circuit 126 provides the stored voltages to the output multiplexer 128, and the output multiplexer 128 generates a voltage corresponding to the column activated by the column sample and hold circuit 126. The ADC 130 receives the voltage generated by the output multiplexer 128, and generates a corresponding code.

The above step is repeated for all the columns. The ADC 130 generates a code corresponding to each column of the plurality of columns. The codes obtained are processed in the processing device 135 coupled to the ADC 130. The processing device 135 generates a test image corresponding to the pixel array 102.

During one test cycle, the control line P1 112 remains selected. In a next test cycle, the control line P2 114 is selected. When control line P1 112 is selected, a fixed test pattern of voltages get coupled to the plurality of columns in the pixel array 102. For example, the column C1 receives the first voltage V1 108, the column C2 receives the second voltage V2 110, and the column CN receives the first voltage V1 108.

Similarly, when control line P2 114 is selected, another fixed test pattern of voltages get coupled to the plurality of columns in the pixel array 102. For example, the column C1 receives the second voltage V2 110, the column C2 receives the first voltage V1 108 and the column CN receives the second voltage V2 110.

Therefore, only 2 test patterns are available on the circuit 100, and hence only 2 test images can be generated by the processing device 135. If more test patterns are required, more control lines similar to P1 and P2 have to be added to the circuit 100 which increases the complexity of the circuit 100. Also, it will impact the area efficiency of the circuit 100. Thus, circuit 100 has very limited use in determining a source of image artifacts in the circuit 100.

The image artifacts are also caused by the output multiplexer 128. The voltages stored in the column sample and hold circuit 126 are processed in a sequential manner by the output multiplexer 128. This reduces a throughput of the circuit 100. The output multiplexer 128 generates an output after every time period T during a test cycle. When a settling time of the output multiplexer 128 is greater than the time period T, it results in artifacts in the image produced using the circuit 100.

Also, since limited test patterns are available in circuit 100 during the test mode, it is difficult to determine which of the rows or columns are causing the output multiplexer 128 to cause image artifacts. The circuit 100 generates fixed vertical stripe images when any one of the control lines P1 and P2 are used. Thus, it is difficult to determine artifacts produced across rows.

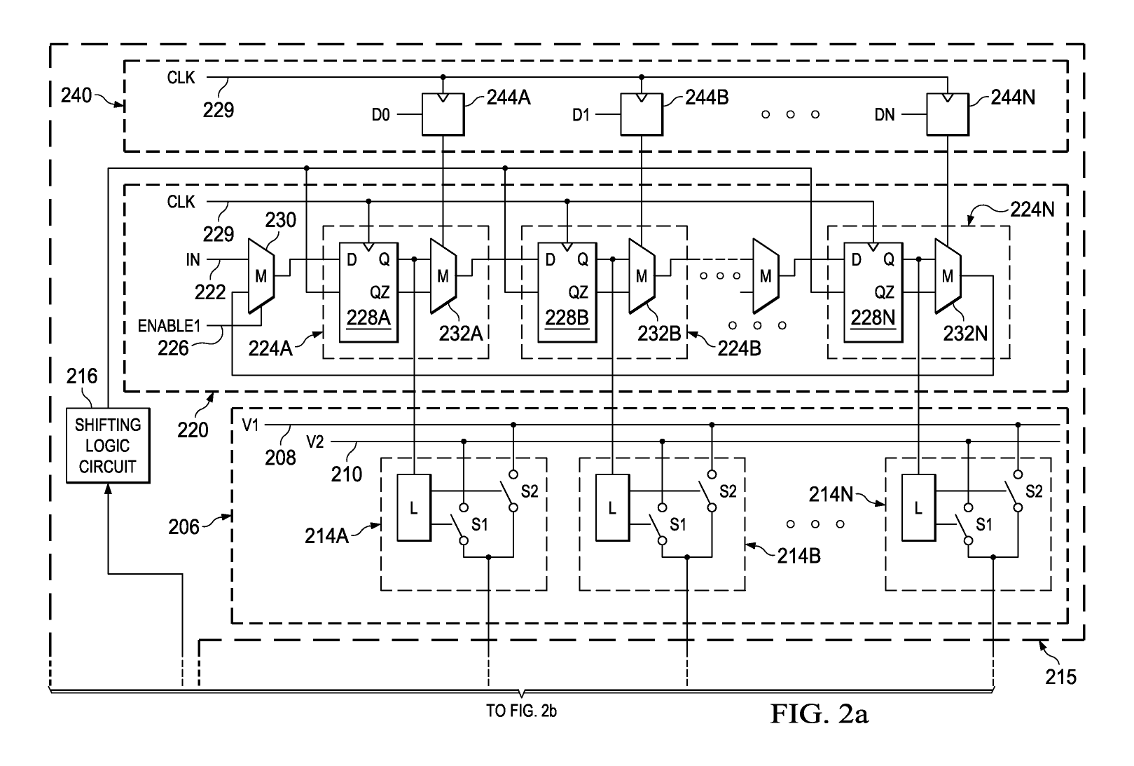

FIG. 2(a) and FIG. 2(b) illustrate a circuit 200, according to an embodiment. The circuit 200 includes a pixel array 202, a row addressing block 204, a built-in-tester 215, a column sample and hold circuit 246, an output multiplexer 248, an analog to digital converter (ADC) 250 and a processing device 255. The pixel array 202 includes a plurality of pixels arranged in a plurality of rows and a plurality of columns. The pixel array 202 is illustrated to have M rows represented as R1, R2 to RM, and N columns represented as C1, C2 to CN. M and N are positive integers greater than or equal to one.

The row addressing block 204, the built-in-tester 215 and the column sample and hold circuit 246 are coupled to the pixel array 202. The built-in-tester 215 is coupled to the row addressing block 204 and the column sample and hold circuit 246. The output multiplexer 248 is coupled to the column sample and hold circuit 246. The ADC 250 is coupled to the output multiplexer 248. The processing device 255 is coupled to the ADC 250.

The built-in-tester 215 includes a control circuit 205, a shifting logic circuit 216, a shift mode selection register 240, a data pattern register 220 and a switching logic circuit 206. In one version, the control circuit 205 is positioned outside the built-in-tester 215. In another version, the functioning of the control circuit 205 is embedded in an external controller used in a device and the circuit 200 is a part of the device. The control circuit 205 is coupled to the row addressing block 204, the column sample and hold circuit 246 and the shifting logic circuit 216. The shift mode selection register 240 is coupled to the shifting logic circuit 216 and the data pattern register 220.

The switching logic circuit 206 is coupled between the data pattern register 220 and the pixel array 202. The shift mode selection register 240 includes a plurality of shift registers illustrated as 244A, 244B to 244N. Each shift register of the plurality of shift registers receive a clock signal CLK 229. Each shift register corresponds to a column of the plurality of columns in the pixel array 202.

For example, the shift register 244A corresponds to column C1, and the shift register 244B corresponds to column C2. The plurality of shift registers stores a shift pattern. Each of the plurality of shift registers receives a bit input. For example, the shift register 244A receives the bit input D0, the shift register 244B receives the bit input D1, and the shift register 244N receives the bit input DN. All the bit inputs are stored in the plurality of shift registers as the shift pattern.

In one example, a user programs the shift pattern in the plurality of shift registers. In another example, the shift pattern is provided by an external circuit. In yet another example, a series of bit inputs is provided to the shift register 244A and at each edge of the clock signal CLK 229, the bits are shifted through the plurality of shift registers. This shifting is terminated once all the shift registers have stored a bit input.

The data pattern register 220 includes an additional multiplexer 230 and a plurality of data blocks illustrated as 224A, 224B to 224N. The data block 224A is a first data block of the plurality of data blocks, and the data block 224N is a last data block of plurality of data blocks. Each data block of the plurality of data blocks corresponds to a column of the plurality of columns in the pixel array 202. For example, the first data block 224A corresponds to the column C1, and the data block 224B corresponds to the column C2. In addition, each data block of the plurality of data blocks receive an output of the shift register of the plurality of shift registers in the shift mode selection register 240.

For example, the first data block 224A receives an output of the shift register 244A, and the data block 224N receives an output of the shift register 244N. Each data block of the plurality of data blocks includes a flip-flop and a multiplexer. For example, the first data block 224A includes a flip-flop 228A and a multiplexer 232A. The data block 224B includes a flip-flop 228B and a multiplexer 232B. Similarly, the last data block 224N includes a flip-flop 228N and a multiplexer 232N.

In each data block, the flip-flop receives the clock signal CLK 229, and an output of the shifting logic circuit 216 as an enable signal. As illustrated, the flip-flop 228A receives the clock signal CLK 229, and the output of the shifting logic circuit 216 as an enable signal. Similarly, the flip-flop 228B receives the clock signal CLK 229 and the output of the shifting logic circuit 216 as an enable signal.

The flip-flop in each data block generates a first output Q and a second output QZ. The multiplexer in a data block receives the first output Q and the second output QZ generated by a flip-flop in the data block. For example, the multiplexer 232A receives the first output Q and the second output QZ generated by the flip-flop 228A. The multiplexer in each data block also receives the output of the shift register as a selection signal. The multiplexer 232A receives the output of the shift register 244A as a selection signal.

The multiplexer 232N receives the first output Q and the second output QZ generated by the flip-flop 228N in the last data block 224N. The multiplexer 232N also receives the output of the shift register 244N as a selection signal. The additional multiplexer 230 in the data pattern register 220 receives an input data IN 222 and an output of the multiplexer 232N in the last data block 224N. The additional multiplexer 230 also receives a selection signal ENABLE1 226, that selects between the input data IN 222 and the output of the multiplexer 232N.

The flip-flop in an Nth data block receives an output of the multiplexer in an N−1th data block. N is a positive integer greater than one. For example, the flip-flop 228B in the data block 224B receives an output of the multiplexer 232A in the first data block 224A.

The switching logic circuit 206 includes a plurality of selection circuits illustrated as 214A, 214B to 214N. Each selection circuit of the plurality of selection circuits corresponds to a column of the plurality of columns. For example, the selection circuit 214A corresponds to the column C1, and the selection circuit 214B corresponds to the column C2. Similarly, the selection circuit 214N corresponds to the column CN.

Each selection circuit of the plurality of selection circuits includes a logic unit, a first switch and a second switch. For example, the selection circuit 214A includes a logic unit L, a first switch S1 and a second switch S2. Similarly, the selection circuit 214B includes a logic unit L, a first switch S1 and a second switch S2. The first switch S1 and the second switch S2 are coupled to the logic unit.

The logic unit L receives the first output of a corresponding flip-flop. For example, the logic unit L in the selection circuit 214A receives the first output Q of the flip-flop 228A. Similarly, the logic unit L in the selection circuit 214B receives the first output Q of the flip-flop 228B. The first switch S1 in each selection circuit receives a second voltage V2 210, and the second switch S2 in each selection circuit receives a first voltage V1 208.

The operation of the circuit 200 illustrated in FIG. 2 is explained now. The control circuit 205 provides a row address to the row addressing block 204. The row addressing block 204 activates a row based on the row address provided by the control circuit 205. The control circuit 205 also provides a column address to the column sample and hold circuit 246. The column sample and hold circuit 246 activates a column based on the column address provided by the control circuit 205.

The circuit 200 operates in a normal mode and a test mode. In the normal mode, the plurality of pixels in the pixel array 202 is charged to a reset voltage. When a sensor having the pixel array 202 receives the light pulses, the plurality of pixels in the pixel array 202 discharge from their original voltage levels. The pixels discharge and attain a voltage lower than the reset voltage based on the intensity of light pulses and exposure time of the pixel array 202 to the light pulses.

The row addressing block 204 activates a row based on the row address provided by the control circuit 205. For example, row R1 is activated by the row addressing block 204. The voltages stored in all the pixels in row R1 is transferred to the column sample and hold circuit 246.

The column sample and hold circuit 246 stores the voltages received from the pixel array 202. The control circuit 205 also provides a column address to the column sample and hold circuit 246. The column sample and hold circuit 246 activates a column based on the column address provided by the control circuit 205.

The column sample and hold circuit 246 provides the stored voltages corresponding to the row R1 to the output multiplexer 248, and the output multiplexer 248 generates a voltage corresponding to the column activated by the column sample and hold circuit 246. The ADC 250 receives the voltage generated by the output multiplexer 248, and generates a corresponding code.

The above step is repeated for all the pixels in row R1. The ADC 250 generates a code corresponding to each pixel in the pixel array 202. The codes obtained corresponding to the pixel array 202 are processed in the processing device 255. The processing device 255 generates an image based on the codes received from the ADC 250.

The circuit 200 also operates in the test mode. In test mode, the shift pattern is stored in the plurality of shift registers, in the shift mode selection register 240. The bit inputs D0, D1 to DN represent the shift pattern stored in the shift mode selection register 240. In one example, a user programs the shift pattern in the plurality of shift register. In another example, the shift pattern is provided by an external circuit. In yet another example, a series of bit inputs is provided to the shift register 244A and at each edge of the clock signal CLK 229, the bits are shifted through the plurality of shift registers. This shifting is terminated once all the shift registers have stored a bit input.

The input data IN 222 is provided to the additional multiplexer 230 in the data pattern register 220. When the circuit 200 is initialized or at the start of a test cycle, the data pattern is shifted through all the flip-flops in the data pattern register 220 at each edge of the clock signal CLK 229. This shifting is terminated once all the flip-flops in the data pattern register 220 have stored a bit of the input data IN 222. In one test cycle, all the rows of the plurality of rows in the pixel array 202 are tested. The data pattern register 220 generates a test pattern corresponding to each row of the plurality of rows in one test cycle.

The control circuit 205 provides a serial number of a row of the plurality of rows, and the row addressing block 204 activates the row based on the serial number received from the control circuit 205. For example, the row R1 is activated by the row addressing block 204. The control circuit 205 also drives the shifting logic circuit 216. Based on the output of the shifting logic circuit 216, the input data IN 222 is shifted through the plurality of data blocks during the test cycle to generate a new input data.

In one example, the control circuit changes the serial number of the row. For example, the row R2 is activated by the row addressing block. The input data IN 222 is shifted through the plurality of data blocks by the shifting logic circuit 216 to generate the new input data based on the shift pattern provided by the shift mode selection register 240. The new input data is stored in the plurality of data blocks of the data pattern register 220.

A test pattern is generated by the data pattern register 220 which includes the first output Q of each flip-flop in the data pattern register 220. The switching logic circuit 206 provides to each column of the plurality of columns, in the pixel array 202, one of the first voltage V1 208 and the second voltage V2 210 corresponding to the test pattern received from the data pattern register 220.

The first voltage V1 208 and the second voltage V2 210 generated is the output from each column of the plurality of columns. The output from each column is received by the column sample and hold circuit 246. The control circuit 205 also provides a column address to the column sample and hold circuit 246. The column sample and hold circuit 246 activates a column based on the column address provided by the control circuit 205.

The column sample and hold circuit 246 stores the voltages received from the plurality of columns in the pixel array 202. The control circuit 205 also provides a column address to the column sample and hold circuit 246. The column sample and hold circuit 246 activates a column based on the column address provided by the control circuit 205.

The column sample and hold circuit 246 provides the stored voltages corresponding to the row R1 to the output multiplexer 248, and the output multiplexer 248 generates a voltage corresponding to the column activated by the column sample and hold circuit 246. The ADC 250 receives the voltage generated by the output multiplexer 248, and generates a corresponding code.

The above step is repeated for all the columns of the plurality of columns. The ADC 250 generates a code corresponding to each pixel in the pixel array 202. The codes obtained corresponding to the pixel array 202 are processed in the processing device 255 coupled to the circuit 200. The processing device 255 generates a test image corresponding to the pixel array 202.

The operation of the circuit 200 in test mode is further illustrated in connection with three situations. In a first situation, it is assumed that the shifting logic circuit 216 does not receive any input from the control circuit 205, and hence does not shift the input data IN 222 through the plurality of data blocks during a test cycle.

Also, the shift pattern stored in the plurality of shift registers in the shift mode selection register 240 is such that the multiplexer in each data block selects the first output Q. In one example, when the shift pattern stored in the plurality of shift registers is logic ‘1’, the multiplexer in each data block (of the plurality of data blocks 224A, 224B to 224N) selects the first output Q of the corresponding flip-flop in the data block.

During initialization of the circuit 200, the input data IN 222 is shifted through all the flip-flops in the data pattern register 220. The test pattern generated by the data pattern register 220 includes the first output Q of each flip-flop. Since, there is no shifting of the input data IN 222 by the shifting logic circuit, and also the shift pattern selects first output Q of each flip-flop, the test pattern remains constant during one test cycle.

Thus, a single test pattern is generated for each row of the plurality of rows in the pixel array 202. The switching logic circuit 206 provides to each column of the plurality of columns, in the pixel array 202, one of the first voltage V1 208 and the second voltage V2 210 corresponding to the test pattern received from the data pattern register 220. In one example, when the first output Q is logic ‘1’, the logic unit L in a selection circuit selects the first voltage V1 208. And, when the first output Q is logic ‘0’, the logic unit L in a selection circuit selects the second voltage V2 210.

The first voltage V1 208 and the second voltage V2 210 generated is the output from each column of the plurality of columns. The output from each column is received by the column sample and hold circuit 246. The conversion of a voltage, corresponding to a pixel in the pixel array 202, to a code has been discussed earlier in connection with FIG. 2 and hence not discussed again for brevity of the description.

In a second situation, the shifting logic circuit 216 receives an input from the control circuit 205 at the same time when the control circuit 205 provides a serial number of a row to be activated by the row addressing block 204. In one version, the shifting logic circuit 216 receives an input from the control circuit 205 after N rows have been activated by the control circuit. For example, in first case, the shifting logic circuit 216 receives an input from the control circuit 205 when the control circuit 205 activates each of rows R1, R2, R3 and R4. In second case, the shifting logic circuit 216 receives an input from the control circuit 205 when the control circuit 205 activates each of rows R1, R3 and R5.

Based on the input received from the control circuit 205, the shifting logic circuit 216 shifts the input data IN 222 through the plurality of data blocks during a test cycle to generate a new input data. The new input data is stored in the plurality of data blocks of the data pattern register 220. Also, the shift pattern stored in the plurality of shift registers in the shift mode selection register 240 is such that the multiplexer in each data block selects the first output Q. In one example, when the shift pattern stored in the plurality of shift registers is logic ‘1’, the multiplexer in each data block (of the plurality of data blocks 224A, 224B to 224N) selects the first output Q of the corresponding flip-flop in the data block.

During initialization of the circuit 200, the input data IN 222 is shifted through all the flip-flops in the data pattern register 220. The test pattern generated by the data pattern register 220 includes the first output Q of each flip-flop. The input data IN 222 is shifted by the shifting logic circuit 216 to generate the new input data. Hence, multiple test patterns are generated in one test cycle. Thus, a test pattern generated for one row is different from at least one test pattern generated for another row of the plurality of rows in the pixel array 202.

The switching logic circuit 206 provides to each column of the plurality of columns, in the pixel array 202, one of the first voltage V1 208 and the second voltage V2 210 corresponding to the test pattern received from the data pattern register 220. In one example, when the first output Q is logic ‘1’, the logic unit L in a selection circuit selects the first voltage V1 208. And, when the first output Q is logic ‘0’, the logic unit L in a selection circuit selects the second voltage V2 210.

The first voltage V1 208 and the second voltage V2 210 generated is the output from each column of the plurality of columns. The output from each column is received by the column sample and hold circuit 246. The conversion of a voltage, corresponding to a pixel in the pixel array 202, to a code has been discussed earlier in connection with FIG. 2 and hence not discussed again for brevity of the description.

In a third situation, the shifting logic circuit 216 receives an input from the control circuit 205 at the same time when the control circuit 205 provides a serial number of a row to be activated by the row addressing block 204. In one version, the shifting logic circuit 216 receives an input from the control circuit 205 after N rows have been activated by the control circuit.

For example, in first case, the shifting logic circuit 216 receives an input from the control circuit 205 when the control circuit 205 activates each of rows R1, R2, R3 and R4. In second case, the shifting logic circuit 216 receives an input from the control circuit 205 when the control circuit 205 activates each of rows R1, R3 and R5. Based on the input received from the control circuit 205, the shifting logic circuit 216 shifts the input data IN 222 through the plurality of data blocks during a test cycle to generate a new input data.

Also, the shift pattern stored in the plurality of shift registers in the shift mode selection register 240 is such that the multiplexers in some data blocks select the first output Q while multiplexer in other data blocks select the second output QZ. In one example, when bit input stored in a shift register is logic ‘1’, the multiplexer in the corresponding data block selects the first output Q, and when the bit input stored in a shift register is logic ‘0’, the multiplexer in the corresponding data block selects the second output QZ.

During initialization of the circuit 200, the input data IN 222 is shifted through all the flip-flops in the data pattern register 220. The input data IN 222 is shifted by the shifting logic circuit 216 to generate the new input data. Also the shift mode selection register 240 selects the first input Q in some multiplexers or the second input QZ in other multiplexers. Thus, multiple test patterns are generated in one test cycle. Thus, a test pattern generated for one row is different from at least one test pattern generated for another row of the plurality of rows in the pixel array 202.

The switching logic circuit 206 provides to each column of the plurality of columns, in the pixel array 202, one of the first voltage V1 208 and the second voltage V2 210 corresponding to the test pattern received from the data pattern register 220. In one example, when the first output Q is logic ‘1’, the logic unit L in a selection circuit selects the first voltage V1 208. And, when the first output Q is logic ‘0’, the logic unit L in a selection circuit selects the second voltage V2 210.

The first voltage V1 208 and the second voltage V2 210 generated is the output from each column of the plurality of columns. The output from each column is received by the column sample and hold circuit 246. The conversion of a voltage, corresponding to a pixel in the pixel array 202, to a code has been discussed earlier in connection with FIG. 2 and hence not discussed again for brevity of the description.

The circuit 200 provides multiple patterns which can be used in test mode. This is very useful in determining source of image artifacts in the circuit 200. The image artifacts are also caused by the output multiplexer 248. The voltages stored in the column sample and hold circuit 246 are processed in a sequential manner by the output multiplexer 248. This reduces a throughput of the circuit 200. The output multiplexer 248 generates an output after every time period T during a test cycle. When a settling time of the output multiplexer 248 is greater than the time period T, it results in artifacts in the final image produced using the circuit 200.

Since, the circuit 200 is capable of generating multiple patterns during the test mode, the rows or the columns that are causing the image artifacts can easily be identified. The circuit 200 generates multiple patterns in one test cycle, and hence it can determine both the artifacts that are produced across rows and the artifacts that are produced across columns of the pixel array 202.

The circuit 200 is capable of generating patterns that can be used to capture pixel level position accuracy which would otherwise have been difficult and time consuming. The circuit 200 can generate test patterns which can be programmed across columns as well as rows of the pixel array 202. The data pattern register 220 along with the shift mode selection register 240 allows generating image patterns which change from one row to another. In addition, the data pattern register 220 and the shift mode selection register 240 provides programmability for shifting either the first output Q or the second output QZ for every column and thus provides flexibility of creating more patterns.

The circuit 200 provides a first voltage V1 208 and a second voltage V2 210 that can be used for each pixel. Thus, for each pixel, two intensity levels can be obtained in the image generated by the processing device. The pixels in the pixel array 202 thus are single ended output pixels.

The pixels in the pixel array 202 can be differential ended pixels in which case, for each pixel, three intensity levels can be obtained in the image generated by the processing device 255 using the first voltage V1 208 and the second voltage V2 210. The three intensity levels in common mode will be V1, V2 and (V1+V2)/2. In differential mode, the three intensity levels will be 0, V1−V2 and V2−V1. Thus, for differential ended pixels, a common mode image is generated and a differential mode image is generated. The common mode image and the differential mode image are used to characterize common mode and differential mode related artifacts respectively.

To achieve the three intensity levels, two shift mode selection register 240 and two data pattern register 220 are required. A pixel will be connected to two columns, a first column and a second column. A shift mode selection register and a data pattern register are coupled to the first column. Another shift mode selection register and another data pattern register are coupled to the second column. The circuit 200 provides multiple variables per column and multiple voltage levels which can be used to generate multiple intensity levels in the test pattern image for both single edged pixels and the differential ended pixels.

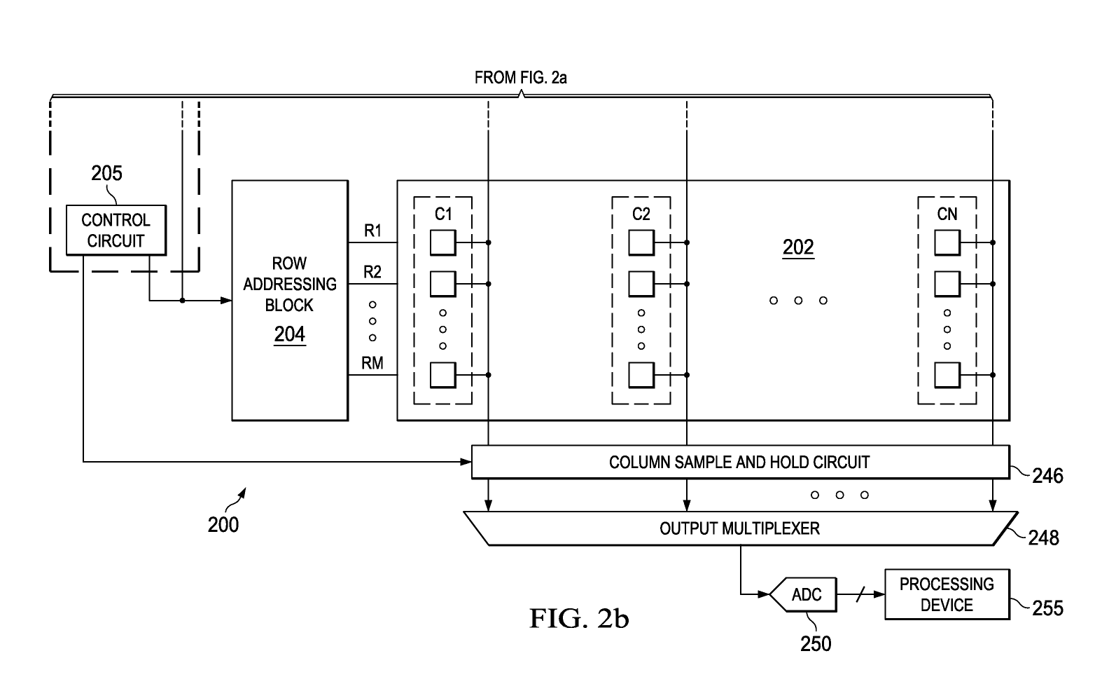

FIG. 3(a) to FIG. 3(i) illustrates test patterns generated by a circuit, according to an embodiment. The FIG. 3(a) to FIG. 3(i) represents test patterns generated by the circuit 200 in test mode.

FIGS. 3(a) to 3(c) represent test patterns generated in a case when the shifting logic circuit 216 does not receive any input from the control circuit 205, and hence does not shift the input data IN 222 through the plurality of data blocks during a test cycle.

Also, the shift pattern stored in the plurality of shift registers in the shift mode selection register 240 is such that the multiplexer in each data block selects the first output Q. In one example, when the shift pattern stored in the plurality of shift registers is logic ‘1’, the multiplexer in each data block (of the plurality of data blocks 224A, 224B to 224N) selects the first output Q of the corresponding flip-flop in the data block.

During initialization of the circuit 200, the input data IN 222 is shifted through all the flip-flops in the data pattern register 220. The test pattern generated by the data pattern register 220 includes the first output Q of each flip-flop. Since, there is no shifting of the input data IN 222 by the shifting logic circuit, and also the shift pattern selects first output Q of each flip-flop, the test pattern remains constant during one test cycle.

Thus, a single test pattern is generated for each row of the plurality of rows in the pixel array 202. The switching logic circuit 206 provides to each column of the plurality of columns, in the pixel array 202, one of the first voltage V1 208 and the second voltage V2 210 corresponding to the test pattern received from the data pattern register 220. In one example, when the first output Q is logic ‘1’, the logic unit L in a selection circuit selects the first voltage V1 208. And, when the first output Q is logic ‘0’, the logic unit L in a selection circuit selects the second voltage V2 210.

In FIG. 3(a) the input data IN 222 is 10101010. Also, the first voltage V1 208 is selected for logic ‘1’, and the second voltage V2 210 is selected for logic ‘0’. Therefore in row R1, for column C1, V1 is selected and for column C2, V2 is selected. In this example, it is assumed that V1 is 0 volt and V2 is 5 volt. Thus, the pattern generated has alternate pixels with low and high intensity. The same pattern is repeated for all the rows.

Similarly, in FIG. 3(b), the input data IN 222 is 00001000. For the same limitations as mentioned in the earlier paragraph for FIG. 3(a), the pattern generated has only one column (fifth column or C5) which is of low intensity. The same pattern is repeated for all the rows.

Similarly, in FIG. 3(c), the input data IN 222 is 11110000. For the same limitations as mentioned for FIG. 3(a), the pattern generated has first 4 columns of low intensity, and the next 4 columns of high intensity. The same pattern is repeated for all the rows.

FIG. 3(d) to FIG. 3(f) represents test patterns generated in a case when the shifting logic circuit 216 receives an input from the control circuit 205 at the same time when the control circuit 205 provides a serial number of a row to be activated by the row addressing block 204. In one version, the shifting logic circuit 216 receives an input from the control circuit 205 after N rows have been activated by the control circuit. For example, in first case, the shifting logic circuit 216 receives an input from the control circuit 205 when the control circuit 205 activates each of rows R1, R2, R3 and R4. In second case, the shifting logic circuit 216 receives an input from the control circuit 205 when the control circuit 205 activates each of rows R1, R3 and R5.

Based on the input received from the control circuit 205, the shifting logic circuit 216 shifts the input data IN 222 through the plurality of data blocks during a test cycle to generate a new input data based on the shift pattern. The new input data is stored in the plurality of data blocks of the data pattern register 220. Also, the shift pattern stored in the plurality of shift registers in the shift mode selection register 240 is such that the multiplexer in each data block selects the first output Q. In one example, when the shift pattern stored in the plurality of shift registers is logic ‘1’, the multiplexer in each data block (of the plurality of data blocks 224A, 224B to 224N) selects the first output Q of the corresponding flip-flop in the data block.

During initialization of the circuit 200, the input data IN 222 is shifted through all the flip-flops in the data pattern register 220. The test pattern generated by the data pattern register 220 includes the first output Q of each flip-flop. The input data IN 222 is shifted by the shifting logic circuit 216 to generate the new input data. Hence multiple test patterns are generated in one test cycle. Thus, a test pattern generated for one row is different from at least one test pattern generated for another row of the plurality of rows in the pixel array 202.

The switching logic circuit 206 provides to each column of the plurality of columns, in the pixel array 202, one of the first voltage V1 208 and the second voltage V2 210 corresponding to the test pattern received from the data pattern register 220.

In FIG. 3(d), the input data IN 222 is 10101010. Also, the shifting logic circuit 216 shifts the input data IN 222 when a new row is activated by the row addressing block 204 to generate a new input data. The first voltage V1 208 is selected for logic ‘1’, and the second voltage V2 210 is selected for logic ‘0’. Therefore in row R1, for column C1, V1 is selected and for column C2, V2 is selected. In this example, it is assumed that V1 is 0 volt and V2 is 5 volt.

Thus, the pattern generated has alternate pixels with low and high intensity. For row R2, the shifting logic circuit 216 shifts the input data In 222 to generate the new input data which is 01010101. Hence, the pattern generated has alternate pixels with high and low intensity. For row R3, the shifting logic circuit 216 again shifts the new input data to generate 10101010. Hence, the pattern generated for row R3 is similar to row R1.

In FIG. 3(e), the input data IN 222 is 10101010. However, the shifting logic circuit 216 shifts the input data IN 222 after every 4 rows to generate a new input data. Thus, for row R1, row R2, row R3 and row R4, the input data IN 222 is 10101010, while for row R3 and row R4, the new input data is 01010101. The first voltage V1 208 is selected for logic ‘1’, and the second voltage V2 210 is selected for logic ‘0’. Therefore in row R1, for column C1, V1 is selected and for column C2, V2 is selected. In this example, it is assumed that V1 is 0 volt and V2 is 5 volt.

In FIG. 3(f), the input data is 01111111, and the shifting logic circuit shifts the input data IN 222 when a new row is activated by the row addressing block 204 to generate a new input data. Thus, for row R2, the shifting logic circuit 216 shifts the input data In 222 to generate the new input data which is 10111111. The first voltage V1 208 is selected for logic ‘1’, and the second voltage V2 210 is selected for logic ‘0’. Therefore in row R1, for column C1, V2 is selected and for column C2, V1 is selected. In this example, it is assumed that V1 is 0 volt and V2 is 5 volt.

FIG. 3(g) to FIG. 3(i) represents test patterns generated in a case when the shifting logic circuit 216 receives an input from the control circuit 205 at the same time when the control circuit 205 provides a serial number of a row to be activated by the row addressing block 204. In one version, the shifting logic circuit 216 receives an input from the control circuit 205 after N rows have been activated by the control circuit.

For example, in first case, the shifting logic circuit 216 receives an input from the control circuit 205 when the control circuit 205 activates each of rows R1, R2, R3 and R4. In second case, the shifting logic circuit 216 receives an input from the control circuit 205 when the control circuit 205 activates each of rows R1, R3 and R5. Based on the input received from the control circuit 205, the shifting logic circuit 216 shifts the input data IN 222 through the plurality of data blocks during a test cycle to generate a new input data.

Also, the shift pattern stored in the plurality of shift registers in the shift mode selection register 240 is such that the multiplexers in some data blocks select the first output Q while multiplexer in other data blocks selects the second output QZ. In one example, when bit input stored in a shift register is logic ‘1’, the multiplexer in the corresponding data block selects the first output Q, and when the bit input stored in a shift register is logic ‘0’, the multiplexer in the corresponding data block selects the second output QZ.

During initialization of the circuit 200, the input data IN 222 is shifted through all the flip-flops in the data pattern register 220. The input data IN 222 is shifted by the shifting logic circuit 216 and to generate a new input data based on the shift pattern. The new input data is stored in the plurality of data blocks of the data pattern register 220. Also, the shift mode selection register 240 selects the first input Q in some multiplexers or the second input QZ in other multiplexers. Thus, multiple test patterns are generated in one test cycle. Thus, a test pattern generated for one row is different from at least one test pattern generated for another row of the plurality of rows in the pixel array 202.

The switching logic circuit 206 provides to each column of the plurality of columns, in the pixel array 202, one of the first voltage V1 208 and the second voltage V2 210 corresponding to the test pattern received from the data pattern register 220.

In FIG. 3(g), the input data IN 222 is 11111111. Also, the shifting logic circuit 216 shifts the input data IN 222 when a new row is activated by the row addressing block 204 to generate a new input data. The shift pattern stored in the plurality of shift registers in the shift mode selection register 240 is such that the multiplexers in all data blocks select the second output QZ.

The first voltage V1 208 is selected for logic ‘1’, and the second voltage V2 210 is selected for logic ‘0’. Therefore in row R1, for all the columns, V1 is selected. In this example, it is assumed that V1 is 0 volt and V2 is 5 volt.

Thus, the pattern generated has all the pixels of low intensity. For row R2, the shifting logic circuit 216 shifts the input data In 222 to generate a new input data based on the shift pattern which is 00000000. Hence, the pattern generated all the pixels with high intensity. For row R3, the shifting logic circuit 216 again shifts the new input data based on the shift pattern to generate 11111111. Hence, the pattern generated for row R3 is similar to row R1.

In FIG. 3(h), the input data IN 222 is 11111111. Also, the shifting logic circuit 216 shifts the input data IN 222 after every 2 rows to generate a new input data based on the shift pattern. The shift pattern stored in the plurality of shift registers in the shift mode selection register 240 is such that the multiplexers in all data blocks select the second output QZ after every 2 rows. Thus, for row R1 and row R2, the input data IN 222 is 11111111, while for row R3 and row R4, the new input data IN is 00000000. The first voltage V1 208 is selected for logic ‘1’, and the second voltage V2 210 is selected for logic ‘0’. Therefore in row R1, for all the columns, V1 is selected and for row 3, for all the columns, V2 is selected. In this example, it is assumed that V1 is 0 volt and V2 is 5 volt.

In FIG. 3(i), the input data IN 222 is 10000000. Also, the shifting logic circuit 216 shifts the input data IN 222 when a new row is activated by the row addressing block 204 to generate a new input data based on the shift pattern. The shift pattern stored in the plurality of shift registers in the shift mode selection register 240 is such that the multiplexer in only last data block selects the second output QZ while other multiplexers select the first output Q. Thus, the new input data generated for row R2 is 11000000, and the new input data generated for row R3 is 11100000. The first voltage V1 208 is selected for logic ‘1’, and the second voltage V2 210 is selected for logic ‘0’. In this example, it is assumed that V1 is 0 volt and V2 is 5 volt.

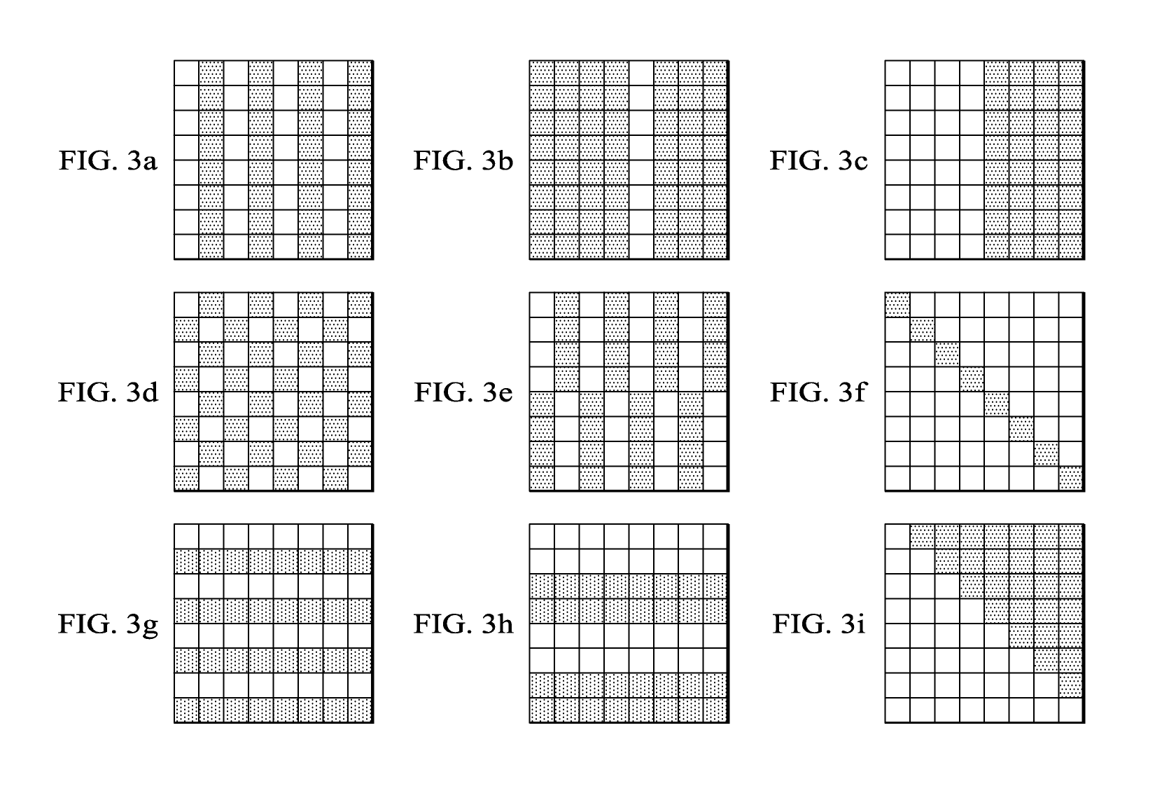

FIG. 4 is a flowchart 400 to illustrate a method of operation of a circuit, according to an embodiment. The flowchart 400 is explained in connection with circuit 200. The flowchart 400, in one example, provides a method of testing a read circuit of a pixel array. The pixel array includes a plurality of pixels arranged in a plurality of rows and a plurality of columns. The pixel array, in one version, is the pixel array 202.

At step 402, a shift pattern is stored. In circuit 200, the plurality of shift registers in the shift mode selection register 240 stores the shift pattern. In one version, the user provides the shift pattern. In another version, the shift version is provided by an external circuit. The shift pattern, in one example, is a sequence of bits inputs. At step 404, an input data is stored in a plurality of data blocks. Each data block of the plurality of data blocks corresponds to a column of the plurality of columns in the pixel array. The input data, in one example, is shifted through the plurality of data blocks during the test cycle. The input data, in another example, is also shifted in the plurality of data blocks to generate a new input data based on the shift pattern. The new input data is stored in the plurality of data blocks.

For example, in circuit 200, the first data block 224A corresponds to the column C1, and the data block 224B corresponds to the column C2. At step 406, a plurality of test patterns is generated corresponding to the plurality of rows. The plurality of test patterns are generated in one test cycle based on the shift pattern and the input data. In one test cycle, all the rows of the plurality of rows in the pixel array are tested.

At step 408, one of a first voltage and a second voltage are provided to each column of the plurality of columns based on a test pattern of the plurality of test patterns generated corresponding to a selected row. In circuit 200, for instance, the control circuit 205 provides a serial number of a row of the plurality of rows, and the row addressing block 204 activates the row based on the serial number received from the control circuit 205.

The first voltage and the second voltage provided to each column is the output from each column of the plurality of columns. The output from each column, in one version, is received by the column sample and hold circuit. An output corresponding to one column of the plurality of columns is selected, and a code is generated based on the output corresponding to the one column.

In circuit 200, the column sample and hold circuit 246 receives the voltages corresponding to each column of the plurality of columns. The output multiplexer 248 selects an output (a voltage) corresponding to the column activated by the column sample and hold circuit 246. The ADC 250 receives the output generated by the output multiplexer 248, and generates a corresponding code.

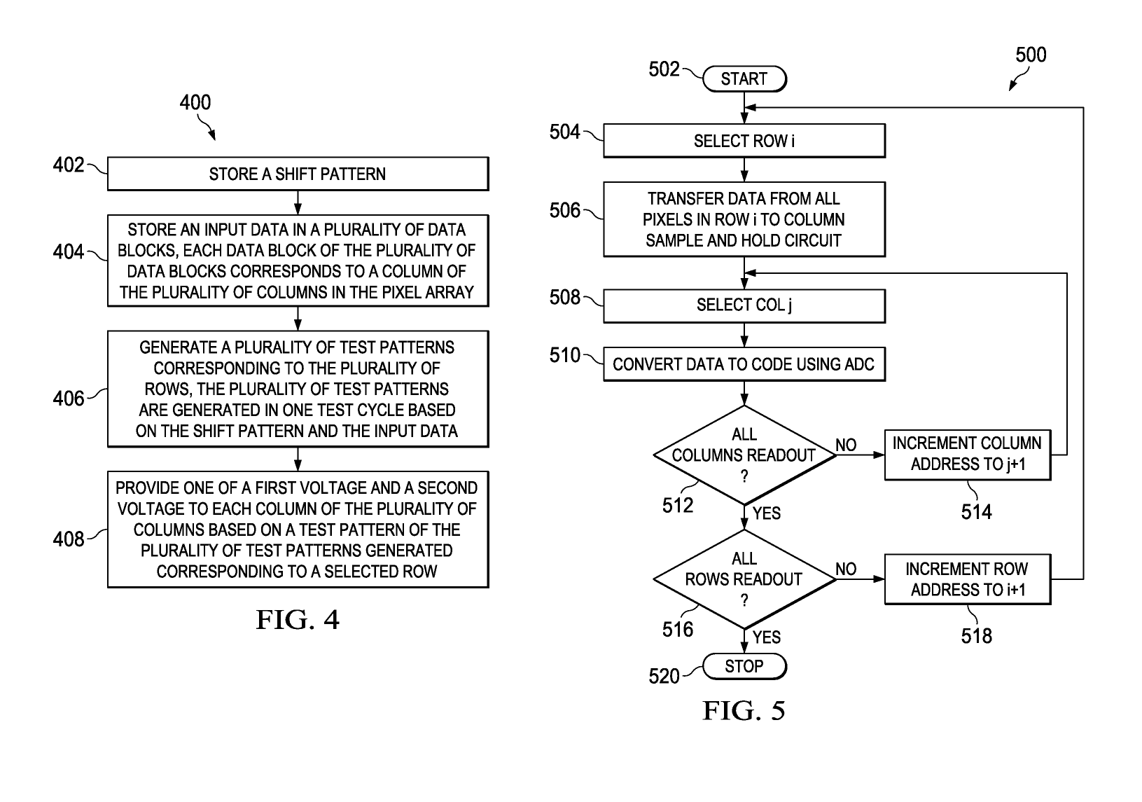

FIG. 5 is a flowchart 500 to illustrate a method of reading a pixel array, according to an embodiment. The flowchart 500 is explained in connection with circuit 200. The system is initialized at step 502. At step 504, a row i is selected. For example, in circuit 200, the row addressing block 204 activates a row based on the row address provided by the control circuit 205. In one example row R1 is selected.

At step 506, the data is transferred from all pixels in row i to column sample and hold circuit. The switching logic circuit 206, in circuit 200, provides to each column of the plurality of columns, in the pixel array 202, one of the first voltage V1 208 and the second voltage V2 210 corresponding to the test pattern received from the data pattern register 220. The first voltage V1 208 and the second voltage V2 210 generated is the output from each column of the plurality of columns. The output from each column is received by the column sample and hold circuit 246.

At step 508, a column j is selected. In circuit 200, the control circuit 205 also provides a column address to the column sample and hold circuit 246. The column sample and hold circuit 246 activates a column based on the column address provided by the control circuit 205.

At step 510, the data is converted to digital using an analog to digital converter (ADC). In circuit 200, the output multiplexer 248 generates a voltage corresponding to the column activated by the column sample and hold circuit 246. The ADC 250 receives the voltage generated by the output multiplexer 248, and generates a corresponding code.

At step 512, it is checked if all the columns in row i are read-out. If the columns are still pending, the system proceeds to step 514. At step 514, the column address is incremented by one to j+1, and the system returns to step 508. For example, the system proceeds from column C1 to column C2. If all the columns in row i have been readout, the system proceeds to step 516.

At step 516, it is checked if all the rows in the pixel array have been readout. If the rows are still pending, the system proceeds to step 518. At step 518, the row address is incremented by one to i+1, and the system returns to step 504. For example, system proceeds from row R1 to row R2. If all the rows have been readout, the system proceeds to step 520 which signifies end of test cycle.

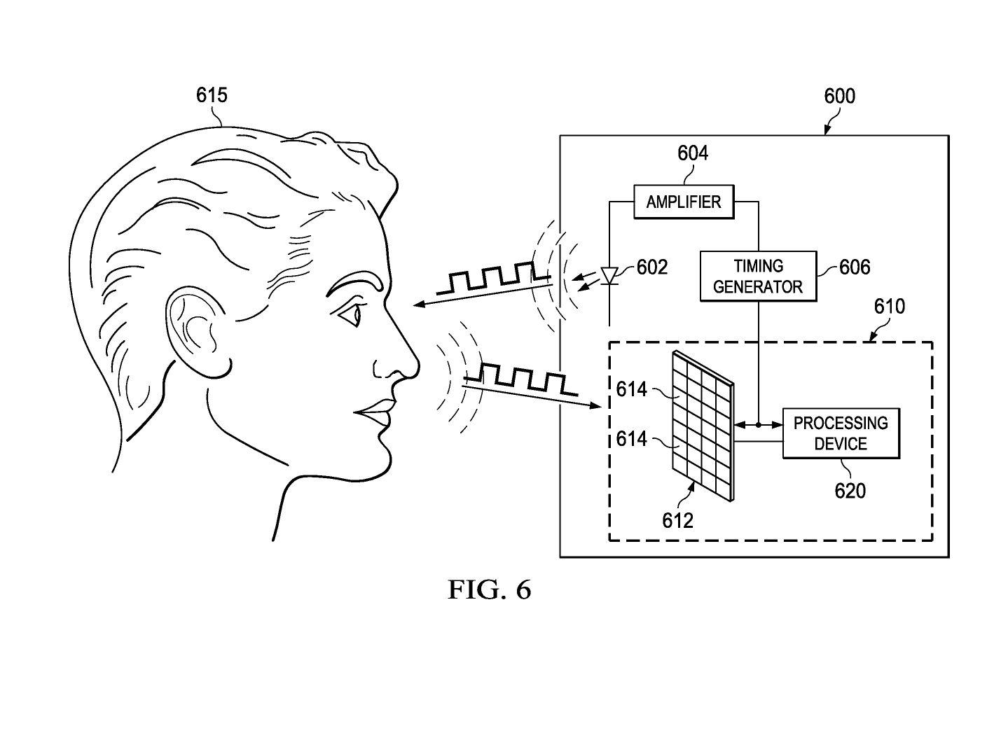

FIG. 6 illustrates a time-of-flight (TOF) system 600, according to an embodiment. The TOF system 600 includes a light source 602, an amplifier 604 and a timing generator 606. The amplifier 604 is coupled to the timing generator 606, and the light source 602 is coupled to the amplifier 604. In one example, the light source 602 is an infrared (IR) light emitting diode (LED) that transmits IR light.

The TOF system 600 also includes a circuit 610. The circuit 610 is analogous to the circuit 200 in connection and operation. The circuit 610 includes a pixel array 612. The pixel array 612 includes one or more pixels illustrated as 614. The pixel array 612 is coupled to a processing device 620. The pixel array 612 is analogous to the pixel array 202, and the processing device 620 is similar in connection and operation to the processing device 255. The circuit 610 also includes a built-in-tester, which further includes a data pattern register and a switching logic circuit. The other components of circuit 200 are not illustrated in circuit 610 for simplicity of the figure.

In one example, one or more processing devices are coupled to the pixel array 612. The processing device 620 can be, for example, a CISC-type (Complex Instruction Set Computer) CPU, RISC-type CPU (Reduced Instruction Set Computer), or a digital signal processor (DSP).

The timing generator 606 generates a clock frequency. The light source 602 emits light pulses at the clock frequency. The light pulses emitted by the light source 602 are reflected from a target 615 to generate reflected light pulses. The pixel array 612 receives the reflected light pulses. The processing device 620 generates an image based on the reflected light pulses received by the pixel array 612.

When the circuit 610 operates in test mode, the circuit 610 provides multiple patterns which can be used in test mode. This is very useful in determining source of image artifacts in the image generated by the processing device. The circuit 610 is capable of generating multiple patterns during the test mode, and the rows or the columns that are causing the image artifacts can easily be identified. The circuit 610 generates multiple patterns in one test cycle, and hence it can determine both the artifacts that are produced across rows and the artifacts that are produced across columns of the pixel array 612.

The foregoing description sets forth numerous specific details to convey a thorough understanding of the invention. However, it will be apparent to one skilled in the art that the invention may be practiced without these specific details. Well-known features are sometimes not described in detail in order to avoid obscuring the invention. Other variations and embodiments are possible in light of above teachings, and it is thus intended that the scope of invention not be limited by this Detailed Description, but only by the following Claims.

What is claimed is:

1. A circuit comprising:
a pixel array having a plurality of pixels arranged in a plurality of rows and a plurality of columns; and
a built-in-tester coupled to the pixel array, the built-in-tester comprising:
a data pattern register configured to generate a plurality of test patterns; and
a switching logic circuit coupled between the data pattern register and the pixel array, the switching logic circuit configured to provide to each column of the plurality of columns one of a first voltage and a second voltage based on a test pattern of the plurality of test patterns received from the data pattern register.

2. The circuit of claim 1, wherein the data pattern register is configured to generate a test pattern corresponding to each row of the plurality of rows in one test cycle.

3. The circuit of claim 1, further comprising:
a row addressing block coupled to the pixel array and configured to activate at least one row of the plurality of rows;
a column sample and hold circuit coupled to the pixel array;
an output multiplexer coupled to the column sample and hold circuit;
an analog to digital converter (ADC) coupled to the output multiplexer; and
a processing device coupled to the ADC.

4. The circuit of claim 1, wherein the built-in-tester further comprises:
a control circuit coupled to the row addressing block and the column sample and hold circuit;
a shifting logic circuit coupled to the control circuit; and
a shift mode selection register, wherein the data pattern register is coupled to the shift mode selection register and the shifting logic circuit.

5. The circuit of claim 4, wherein the shift mode selection register comprises a plurality of shift registers, and each shift register of the plurality of shift registers corresponds to a column of the plurality of columns in the pixel array, the plurality of shift registers configured to store a shift pattern.

6. The circuit of claim 1, wherein the data pattern register comprises:
an additional multiplexer; and
a plurality of data blocks, and each data block of the plurality of data blocks corresponds to a column of the plurality of columns in the pixel array, and each data block of the plurality of data blocks receive an output of the shift register of the plurality of shift registers.

7. The circuit of claim 6, wherein each data block of the plurality of data blocks comprises:
a flip-flop configured to receive a clock signal and an output of the shifting logic circuit as an enable signal, the flip-flop configured to generate a first output and a second output; and
a multiplexer configured to receive the output of the shift register as a selection signal, the multiplexer configured to receive the first output and the second output from the flip-flop.

8. The circuit of claim 6, wherein:
the additional multiplexer receives an input data and an output of a multiplexer in a last data block of the plurality of data blocks;
the flip-flop in a first data block of the plurality of data blocks receive an output of the additional multiplexer; and
the flip-flop in an Nth data block receives an output of a multiplexer in an N−1th data block, where N is a positive integer greater than one.

9. The circuit of claim 6, wherein the test pattern generated by the data pattern register is formed from the first output of each flip-flop in the plurality of data blocks.

10. The circuit of claim 1, wherein the switching logic circuit comprises a plurality of selection circuits, each selection circuit of the plurality of selection circuits corresponds to a column of the plurality of columns.

11. The circuit of claim 10, wherein each selection circuit of the plurality of selection circuits comprises:
a logic unit configured to receive the first output of a corresponding flip-flop;
a first switch coupled to the logic unit, and configured to receive the second voltage; and
a second switch coupled to the logic unit, and configured to receive the first voltage.

12. The circuit of claim 1, wherein the column sample and hold circuit is configured to receive an output from each column of the plurality of columns.

13. The circuit of claim 1, wherein the output multiplexer is configured to generate an output corresponding to one column of the plurality of columns, and the ADC is configured to generate a code based on the output of the multiplexer.

14. The circuit of claim 1, wherein:
the shift pattern is stored in the plurality of shift registers;
the input data provided to the additional multiplexer is shifted through the plurality of data blocks by the shifting logic circuit;
the test pattern is generated by the data pattern register based on the input data and the shift pattern;
the control circuit provides a serial number of a row of the plurality of rows;
the switching logic circuit provides to each column of the plurality of columns one of the first voltage and the second voltage corresponding to the test pattern received from the data pattern register, wherein the first voltage and the second voltage generated is the output from each column of the plurality of columns;
the control circuit changes the serial number of the row; and
the input data is shifted through the plurality of data blocks by the shifting logic circuit to generate a new input data based on the shift pattern, the new input data is stored in the plurality of data blocks.

15. A method of testing a read circuit of a pixel array, the pixel array comprising a plurality of pixels arranged in a plurality of rows and a plurality of columns, the method comprising:
storing a shift pattern;
storing an input data in a plurality of data blocks, each data block of the plurality of data blocks corresponds to a column of the plurality of columns in the pixel array;
generating a plurality of test patterns corresponding to the plurality of rows, the plurality of test patterns are generated in one test cycle based on the shift pattern and the input data; and
providing one of a first voltage and a second voltage to each column of the plurality of columns based on a test pattern of the plurality of test patterns generated corresponding to a selected row.

16. The method of claim 15 further comprising generating a test pattern corresponding to each row of the plurality of rows in one test cycle.

17. The method of claim 15, further comprising:
receiving an output from each column of the plurality of columns;
selecting an output corresponding to one column of the plurality of columns; and
generating a code based on the output corresponding to the one column.

18. The method of claim 15 further comprising shifting the input data stored in the plurality of data blocks to generate a new input data based on the shift pattern, and storing the new input data in the plurality of data blocks.

19. A time-of-flight (TOF) system comprising:
a light source for emitting light pulses; and
a circuit, the circuit comprising:
a pixel array having a plurality of pixels arranged in a plurality of rows and a plurality of columns; and
a built-in-tester coupled to the pixel array, the built-in-tester comprising:
a data pattern register configured to generate a plurality of test patterns; and
a switching logic circuit coupled between the data pattern register and the pixel array, the switching logic circuit configured to provide to each column of the plurality of columns one of a first voltage and a second voltage based on a test pattern of the plurality of test patterns received from the data pattern register.

20. The TOF system of claim 19 further comprising:
a row addressing block coupled to the pixel array and configured to activate at least one row of the plurality of rows;
a column sample and hold circuit coupled to the pixel array;
an output multiplexer coupled to the column sample and hold circuit;
an analog to digital converter (ADC) coupled to the output multiplexer; and
a processing device coupled to the ADC.
